(19) United States
(12) Patent Application Publication
(10) Pub. No.: US 2025/0140561 A1
(43) Pub. Date: May 1, 2025

(54) PROCESSING METHOD OF WAFER

(71) Applicant: DISCO CORPORATION, Tokyo (JP)

(72) Inventor: Tsubasa HIROSE, Tokyo (JP)

(21) Appl. No.: 18/910,171

(22) Filed: Oct. 9, 2024

(30) Foreign Application Priority Data
Nov. 1, 2023 (JP) 2023-187597

(51) Int. Cl. H01L 21/268; H01L 21/78

(52) U.S. Cl. CPC H01L 21/268; H01L 21/78

(57) ABSTRACT

Disclosed is a processing method of a wafer. The method includes the following steps: irradiating the wafer with a first laser beam with its focal point sequentially positioned on respective dicing lines near a front surface whereby first modified layers are formed, irradiating the wafer with a second laser beam of a higher power with its focal point sequentially positioned corresponding to the respective dicing lines on an inner side of a back surface whereby second modified layers are formed, irradiating the wafer with the second laser beam with its focal point sequentially positioned between the first modified layers and the second modified layers whereby third modified layers are formed and straight cracks are allowed to appear on the front surface, and applying an external force to the wafer whereby the wafer is divided into individual device chips.

### BACKGROUND OF THE INVENTION

### Field of the Invention

The present invention relates to a processing method of a wafer, on which a plurality of devices is formed on a front surface thereof and is defined by a plurality of intersecting dicing lines, by dividing the wafer into individual device chips.

### Description of the Related Art

A wafer with a plurality of devices such as integrated circuits (ICs) or large-scale integration (LSI) circuits formed on a front surface thereof and defined by a plurality of intersecting dicing lines is divided into individual device chips by a laser processing machine, and the divided device chips are used in electronic equipment such as mobile phones or personal computers.

The laser processing machine includes a chuck table that holds the wafer, a laser beam irradiation unit that irradiates the wafer, which is held on the chuck table, with a laser beam of a wavelength having transmissivity for the wafer, with a focal point of the laser beam positioned corresponding to each dicing line, respectively, inside the wafer, and a feed mechanism that causes a relative processing feed of the chuck table and the laser beam irradiation unit, and is known to enable precise formation of shield tunnels, which are each formed of a fine hole and a modified layer surrounding the fine hole, as division starting points corresponding to the dicing lines inside the wafer by appropriately setting laser processing conditions (see, for example, JP 2014-221483A).

In a wafer with light-emitting diodes (LEDs), power devices, or the like formed thereon, hard silicon carbide (SiC), gallium nitride (GaN), diamond, sapphire, or the like is used as a substrate. Irradiation with a laser beam of relatively high power is therefore needed for the formation of modified layers as division starting points.

### SUMMARY OF THE INVENTION

If modified layers are formed inside a hard wafer by irradiating a laser beam of high power in order to form division staring points in the wafer, however, cracks that occur from the modified layers meander when they reach a front surface of the wafer, thereby raising a problem that the cracks are offset from dicing lines. If the wafer under such conditions is divided into individual device chips, another problem arises in that the divided device chips may have lowered quality.

The present invention therefore has, as an object thereof, the provision of a processing method of a wafer, which allows straight cracks to appear in dicing lines without meandering along the dicing lines, and hence enables appropriate division of the wafer with high precision.

In accordance with an aspect of the present invention, there is provided a processing method of a wafer, on which a plurality of devices is formed on a front surface thereof and is defined by a plurality of intersecting dicing lines, by dividing the wafer into individual device chips. The processing method includes a first processing step of irradiating the wafer with a first laser beam of a wavelength having transmissivity for the wafer and of a first power with a focal point of the first laser beam sequentially positioned on the respective dicing lines near the front surface whereby first modified layers are formed with no cracks reaching the front surface along the respective dicing lines, a second processing step of irradiating the wafer with a second laser beam of a wavelength having transmissivity for the wafer and of a second power higher than the first power with a focal point of the second laser beam sequentially positioned corresponding to the respective dicing lines on an inner side of a back surface of the wafer whereby second modified layers are formed along the respective dicing lines, a third processing step of irradiating the wafer with the second laser beam with the focal point of the second laser beam sequentially positioned between the first modified layers and the second modified layers which correspond to the first modified layers, respectively, whereby third modified layers are formed extending from the second modified layers to the first modified layers, respectively, and, at the same time, straight cracks are allowed to appear on the front surface of the wafer, where the dicing lines are formed, along the dicing lines, and a dividing step of applying an external force to the wafer whereby the wafer is divided into the individual device chips.

Preferably, the first modified layers, the second modified layers, and the third modified layers may each be constituted of a shield tunnel that is formed of a fine hole and an amorphous region surrounding the fine hole. Preferably, the wafer may be irradiated from the front surface with the first laser beam in the first processing step, and with the second laser beam in the second and third processing steps. Preferably, the wafer may be selected from a group consisting of a silicon carbide wafer, a gallium nitride wafer, a diamond wafer, and a sapphire wafer.

According to the processing method of the present invention, relatively large straight cracks are formed in the wafer without meandering along the dicing lines before the dividing step is performed. It is therefore possible to reduce dividing load when the dividing step is performed, and also to appropriately divide the wafer into individual device chips with high precision without causing chipping.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is an overall perspective view of a laser processing machine suitable for practicing a processing method according to an embodiment of the present invention for a wafer;

FIG. 2 is a perspective view of a frame unit including the wafer to which processing is applied by the laser processing machine depicted in FIG. 1;

FIG. 3 is a perspective view depicting how a first processing step of the processing method is performed;

FIG. 4A is an enlarged fragmentary cross-sectional view of the wafer subjected to the first processing step and including shield tunnels formed therein;

FIG. 4B is a concept diagram of each shield tunnel formed in the first processing step depicted in FIG. 4A;

FIG. 5A is a perspective view depicting how a second processing step of the processing method is performed;

FIG. 5B is an enlarged fragmentary cross-sectional view of the wafer subjected to the second processing step depicted in FIG. 5A and including therein the resulting second modified layers (shield tunnels) in addition to the shield tunnels formed in the first processing step;

FIG. 6A is a perspective view depicting how a third processing step of the processing method is performed;

FIG. 6B is an enlarged fragmentary cross-sectional view of the wafer subjected to the third processing step depicted in FIG. 6A, and including therein the resulting third modified layers (shield tunnels) in addition to the first and second modified layers (shield tunnels) formed in the first processing step and the second processing step, respectively;

FIG. 6C is an enlarged fragmentary cross-sectional view of the wafer subjected to a processing step similar to the third processing step, and including therein additional third modified layers (shield tunnels) formed between the second modified layers (shield tunnels) and the third modified layers (shield tunnels), along with straight cracks allowed to appear in dicing lines on a front surface of the wafer;

FIG. 7 includes a perspective view and enlarged fragmentary view of the frame unit including the wafer with the straight cracks formed in the dicing lines by the processing method similar to the third processing step; and

FIG. 8 is a cross-sectional view depicting how a dividing step of the processing method is performed.

### DETAILED DESCRIPTION OF THE PREFERRED EMBODIMENT

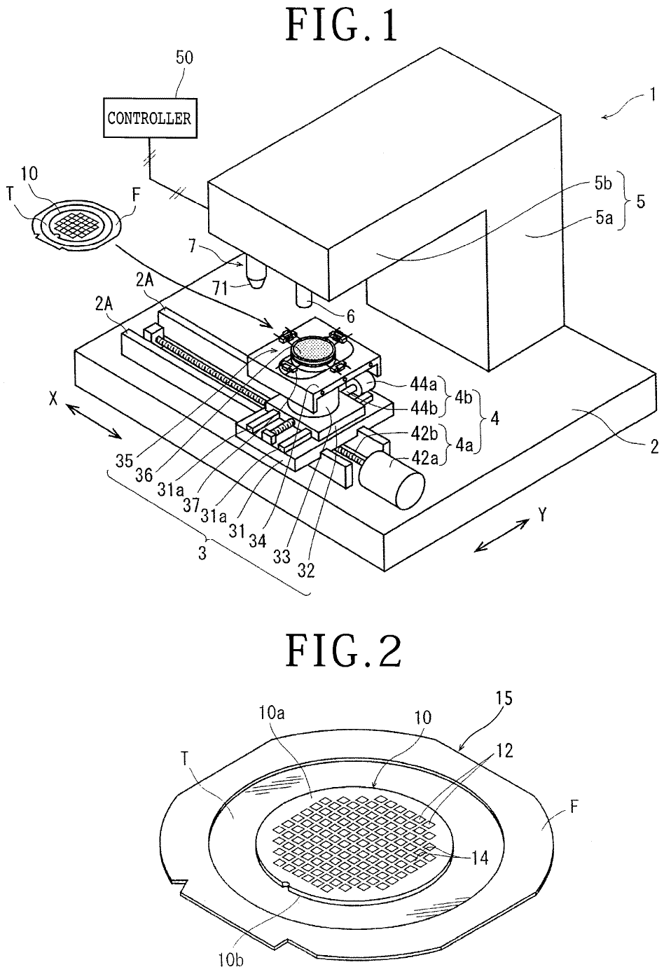

With reference to the attached drawings, a description will hereinafter be made in detail about a processing method according to an embodiment of the present invention for a wafer. FIG. 1 depicts a laser processing machine 1 suitable for practicing the processing method of this embodiment. The laser processing machine 1 is arranged on a bed 2, and includes at least a holding unit 3 that holds a wafer 10 as a workpiece, a laser beam irradiation unit 7 that irradiates the wafer 10, which is held on the holding unit 3, with a laser beam. It is to be noted that, as depicted, for example, in FIG. 2, the wafer 10 to be divided by the processing method of this embodiment is a SiC wafer with a plurality of devices 12 formed on a front surface 10a and defined by a plurality of intersecting dicing lines 14, has a thickness of approximately 500 μm, is integrated as a frame unit 15 by bonding a self-adhesive tape T to an annular frame F and a back surface 10b of the wafer 10, and is supported on the annular frame F via the self-adhesive tape T.

The laser processing machine 1 includes an alignment unit 6 that performs an alignment by imaging the wafer 10 held on the holding unit 3, a moving mechanism 4 that moves the holding unit 3, a column 5 constructed of a vertical base portion 5a disposed upright beside the moving mechanism 4 on the bed 2 and a horizontal head portion 5b extending in a horizontal direction from an upper end portion of the vertical base portion 5a, a controller 50, and a display unit (depiction omitted).

As depicted in FIG. 1, the holding unit 3 includes a rectangular X-axis direction movable plate 31 mounted movably in an X-axis direction on the bed 2, a rectangular Y-axis direction movable plate 32 mounted movably in a Y-axis direction on the X-axis direction movable plate 31, a cylindrical support post 33 fixed on an upper surface of the Y-axis direction movable plate 32, and a rectangular cover plate 34 fixed on an upper end of the support post 33. On the cover plate 34, a chuck table 35 is arranged extending upward through a slot formed in the cover plate 34. On an upper surface of the chuck table 35, a circular suction chuck 36 is arranged. The suction chuck 36 is formed from a porous material having air permeability, and uses, as a holding surface, an X-Y plane specified by X-coordinates and Y-coordinates. The suction chuck 36 is connected to suction means, free of depiction, via a flow channel extending through the support post 33, and around the suction chuck 36, four clamps 37 are arranged at equal intervals for use in grasping the annular frame F when the wafer 10 is held on the chuck table 35. By operating the suction means, the wafer 10 can be held under suction on the suction chuck 36.

The moving mechanism 4 includes an X-axis moving mechanism 4a that moves the chuck table 35 in the X-axis direction, a Y-axis moving mechanism 4b that moves the chuck table 35 in the Y-axis direction, and a rotary drive mechanism (not depicted) that is accommodated in the support post 33 and rotates the chuck table 35. The X-axis moving mechanism 4a converts rotary motion of a motor 42a into linear motion via a ball screw 42b, transmits the linear motion to the X-axis direction movable plate 31, and moves the X-axis direction movable plate 31 in the X-axis direction along a pair of guide rails 2A arranged along the X-axis direction on the bed 2. On the other hand, the Y-axis moving mechanism 4b converts rotary motion of a motor 44a into linear motion via a ball screw 44b, transmits the linear motion to the Y-axis direction movable plate 32, and moves the Y-axis direction movable plate 32 in the Y-axis direction along a pair of guide rails 31a arranged along the Y-axis direction on the X-axis direction movable plate 31.

Inside the horizontal head portion 5b of the column 5, an optical system, which constitutes the above-described laser beam irradiation unit 7, and the alignment unit 6 are accommodated. On a side of a lower surface of a distal end portion of the horizontal head portion 5b, a condenser 71 is arranged. The condenser 71 constitutes a part of the laser beam irradiation unit 7, and includes a condenser lens (depiction omitted) that condenses a laser beam and irradiates the wafer 10 with the condensed laser beam. The repetition frequency, average power, and the like of the laser beam to be irradiated from the laser beam irradiation unit 7 are appropriately adjusted by the controller 50.

The alignment unit 6 is imaging means for imaging the wafer 10 held on the holding unit 3, and detecting a position or the like to which the laser beam is to be irradiated, and can detect the height of the front surface 10a of the wafer 10 from the suction chuck 36, as a reference, that constitutes the holding surface of the chuck table 35, in other words, the thickness of the wafer 10. The alignment unit 6 is arranged at a position adjacent in the X-axis direction, which is indicated by the arrow X in the figure, to the above-described condenser 71.

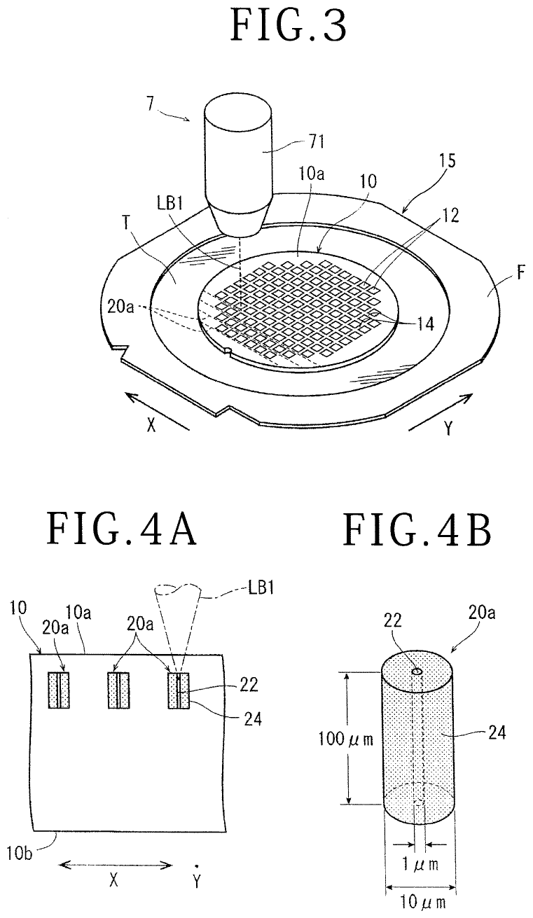

The laser processing machine 1 used in the processing method of this embodiment is configured to enable irradiation of the wafer 10 with a first laser beam LB1 (see FIG. 3) of a wavelength having transmissivity for the wafer 10 and of a relatively low power, and also irradiation of the wafer 10 with a second laser beam LB2 (see FIGS. 5A and 5B) of a wavelength having transmissivity for the wafer 10 and of a relatively high power.

The controller 50 is constituted by a computer, and includes a central processing unit (CPU) that conducts computation processing in accordance with control programs, a read-only memory (ROM) that stores the control programs and the like, a read/write random-access memory (RAM) that temporarily stores detection values, computation results, and the like, an input interface, and an output interface (free of depictions about their details). To the controller 50, the alignment unit 6, the laser beam irradiation unit 7, the X-axis moving mechanism 4a, the Y-axis moving mechanism 4b, the display unit (free of depiction), and the like are connected. Further, image data captured by the alignment unit 6 are appropriately stored in the random-access memory, and the detected image data, laser processing conditions, and the like are displayed on the display unit.

The laser processing machine 1 in this embodiment generally has the configurations as described above, and a description will hereinafter be made about the processing method that divides the wafer 10 into individual device chips using the laser processing machine 1.

### (First Processing Step)

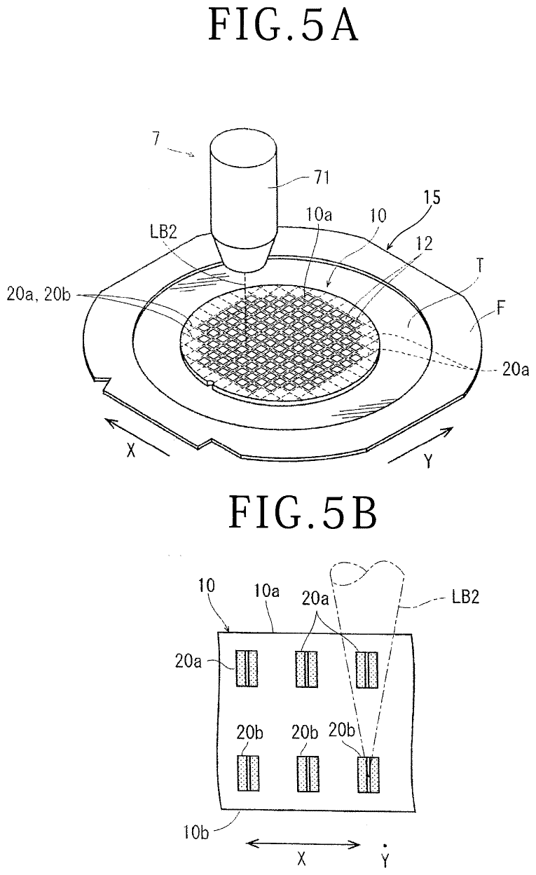

This first processing step forms first modified layers with no cracks reaching the front surface 10a of the wafer 10 along the respective dicing lines 14 by irradiating the wafer 10 with the first laser beam LB1 of the wavelength having transmissivity for the wafer 10 and of the relatively low power with a focal point of the first laser beam LB1 sequentially positioned corresponding to the respective dicing lines 14 near the front surface 10a. With reference to FIGS. 3 and 4, the first processing step will hereinafter be described more specifically.

When this first processing step is to be performed, one of wafers 10 is unloaded from a cassette (free of depiction) in which the wafers 10 are accommodated, and is placed and held under suction on the suction chuck 36 of the chuck table 35, and further, the annular frame F is grasped and fixed by the clamps 37.

The above-described moving mechanism 4 is next operated to move the wafer 10 right below the alignment unit 6, the wafer 10 is imaged, and the dicing lines 14 in a first direction (hereinafter referred to as “the first direction dicing lines 14”) formed on the front surface 10a of the wafer 10 are brought into alignment with the X-axis direction. In addition, the positions of opposite ends of each of the first direction dicing lines 14 along which processing is applied on the front surface 10a of the wafer 10 are each specified by X-coordinates and a Y-coordinate, and further the height of the front surface 10a at each of the first direction dicing lines 14 is detected. These coordinates and heights are stored in appropriate one of the memories of the controller 50.

The above-described X-axis moving mechanism 4a and Y-axis moving mechanism 4b are then operated so that, as depicted in FIG. 3, a predetermined one of the first direction dicing lines 14 of the wafer 10 is moved right below the condenser 71 of the above-described laser beam irradiation unit 7. Here, a focal-point position adjustment unit (depiction omitted) is operated by the controller 50 so that, as depicted in FIG. 4A, the focal point of the first laser beam LB1 is positioned near the front surface 10a, on which the first laser beam LB1 impinges.

After the focal point of the first laser beam LB1 has been positioned as described above, the laser beam irradiation unit 7 is operated so that, as depicted in FIG. 3, the first laser beam LB1 is irradiated from the condenser 71, and the X-axis moving mechanism 4a is also operated so that, as depicted in FIG. 4A, a first row of first modified layers 20a, which are each constituted of a shield tunnel formed of a fine hole and an amorphous region surrounding the fine hole, is formed along the predetermined one dicing line 14 inside the wafer 10. Now, as depicted in FIG. 4B, the shield tunnels that constitute the first row of the first modified layers 20a are each constituted of a fine hole 22, which is formed centrally and has a diameter of approximately 1 μm, and an amorphous region 24, which surrounds the fine hole 22 and has a diameter of 10 μm. An interval of approximately 50 μm is formed between upper ends of the first modified layers 20a formed at this time and the front surface 10a of the wafer 10, so that the first modified layers 20a do not appear on a side of the front surface 10a of the wafer 10, and cracks which occur using the first modified layers 20a as starting points do not appear in the front surface 10a either.

It is to be noted that the first processing step in the present invention is not limited to the formation of the shield tunnels as the first modified layers 20a along each dicing line 14 as described above, and may also include forming only modified layers without centrally having fine holes 22. In order to allow the formation of appropriate cracks by performing the processing method of this embodiment, however, it is preferred to form, as each first modified layer 20a, such a shield tunnel as described above, which includes the fine hole 22 and the amorphous region 24 surrounding the fine hole 22. For the formation of such first modified layers 20a, it is important that, as also described in JP 2014-221483A referred to above, the value (NA/N) obtained by dividing the number of apertures (NA) of the condenser lens (depiction omitted), which is arranged in the condenser 71, by the refractive index (N) of a substrate (SiC in this embodiment), which constitutes the wafer 10, is set to fall in the range of 0.05 to 0.2.

After the above-described first modified layers 20a have been formed along the predetermined one of the first direction dicing lines 14, the Y-axis moving mechanism 4b is operated, the wafer 10 is indexed and fed in the Y-axis direction by the interval between each two adjacent dicing lines 14, and another first direction dicing line 14 that is adjacent in the Y-axis direction to the predetermined one first direction dicing line 14 and has not been processed yet is positioned right below the condenser 71. In a similar manner to that in the above, the wafer 10 is then irradiated with the first laser beam LB1 with the focal point of the laser beam LB1 positioned on the adjacent first direction dicing line 14 near the front surface 10a inside the wafer 10, and the wafer 10 is thereafter processed and fed in the X-axis direction to form similar first modified layers 20a as a second row. Processing feed in the X-axis direction and indexing feed in the Y-axis direction of the wafer 10 are alternately repeated as in the above, whereby the first modified layers 20a are formed as a first layer group inside all the dicing lines 14 that extend along the first direction.

The above-described rotary drive mechanism is next operated to rotate the wafer 10 90 degrees, whereby the dicing lines 14 in a second direction (hereinafter referred to as “the second direction dicing lines 14”), which are orthogonal to the first direction dicing lines 14 with the first modified layers 20a already formed therein and have not been processed yet, are brought into alignment with the X-axis direction. By similar procedures as those described above, the wafer 10 is then also irradiated with the first laser beam LB1 with the focal point of the first laser beam LB1 sequentially positioned inside the remaining respective dicing lines 14, followed by operations of the X-axis moving mechanism 4a and the Y-axis moving mechanism 4b so that first modified layers 20a are formed along all the dicing lines 14, which are formed on the front surface 10a of the wafer 10, inside the wafer 10.

Here, laser processing conditions (hereinafter referred to as “the first processing conditions”) when the first modified layers 20a are formed near the front surface 10a in the first processing step of this embodiment may be set, for example, as described below.
Wavelength: 1,064 nm
Repetition frequency: 1 kHz
Average power: 0.25 W
Processing feed rate: 25 mm/s

If the first modified layers 20a are formed by applying the first laser beam LB1 near the front surface 10a of the wafer 10 on the basis of the above-described first processing conditions, the shield tunnels that constitute the first modified layers 20a have a height in the thickness direction of approximately 100 μm. Further, an interval of approximately 15 μm is formed between each two shield tunnels adjacent each other in the X-axis direction themselves, because the distance between the centers of the two adjacent shield tunnels is calculated to be 25 μm at the above-described repetition frequency and processing feed rate. Furthermore, no cracks are allowed to appear along the dicing lines 14 in the front surface 10a of the wafer 10 in the first processing step, because the average power is set relatively low (at 0.25 W). The first processing step has now been completed.

### (Second Processing Step)

After the above-described first processing step has been performed, a second processing step is performed. In the second processing step, second modified layers are formed by irradiating the wafer 10 with the second laser beam LB2 of the wavelength having transmissivity for the wafer 10 and of the relatively high power, more specifically, of a power higher than the above-described first laser beam LB1 with a focal point of the second laser beam LB2 sequentially positioned at locations corresponding to the respective dicing lines 14 inside the back surface 10b. This second processing step will hereinafter be described specifically.

When the second processing step is to be performed, a predetermined one dicing line 14 with the first modified layers 20a formed therein is positioned right below the condenser 71 of the above-described laser beam irradiation unit 7 as depicted in FIG. 5A. Here, the laser beam irradiation unit 7 is set by the controller 50 such that the second laser beam LB2 of the wavelength having transmissivity for the wafer 10 and of the relatively high power, more specifically, of an average power higher than the first laser beam LB1 is irradiated.

Now, as depicted in FIG. 5B, in the second processing step, the wafer 10 is irradiated with the second laser beam LB2 with the focal point of the second laser beam LB2 positioned closer to the back surface 10b inside the wafer 10, and, in addition, the X-axis moving mechanism 4a is operated, so that a first row of second modified layers 20b is formed along a predetermined one of the first-direction dicing lines 14 near the back surface 10b of the wafer 10. As with the first modified layers 20a, the second modified layers 20b are each preferably formed of a fine hole and an amorphous region surrounding the fine hole. It is to be noted that an interval of approximately 50 μm is formed between lower ends of the second modified layers 20b and the back surface 10b of the wafer 10.

With the second laser beam LB2 sequentially irradiated along the respective dicing lines 14, the moving mechanism 4 is operated as in the above-described formation of the first modified layers 20a, whereby the second modified layers 20b are formed as a second layer group at the above-described locations in the thickness direction along all the dicing lines 14 of the wafer 10. The second processing step has now been completed. It is to be noted that, as a condenser lens to be used upon formation of the second modified layer 20b as the second layer group, one satisfying similar conditions as the condenser lens used upon formation of the first modified layers 20a as the first layer group is selected.

When the above-described second processing is performed, laser processing conditions (hereinafter referred to as “the second processing conditions”) are different from the first processing conditions in that the power is higher. The second processing conditions may be set, for example, as described below.
Wavelength: 1,064 nm
Repetition frequency: 1 kHz
Average power: 0.5 W
Processing feed rate: 25 mm/s

As the repetition frequency and processing feed rate in the above-described second processing conditions are set under the same conditions as those in the first processing conditions, the interval between each two adjacent ones of the shield tunnels which constitute the second modified layers 20b is equal to the interval between each two adjacent ones of the shield tunnels which constitute the first modified layers 20a. Even when these second modified layers 20b are formed, this formation of the second modified layers 20b in addition to the first modified layers 20a does not allow cracks to appear in the front surface 10a or back surface 10b of the wafer 10 because the intervals of each two adjacent modified layers 20a as shield tunnels are large.

### (Third Processing Step)

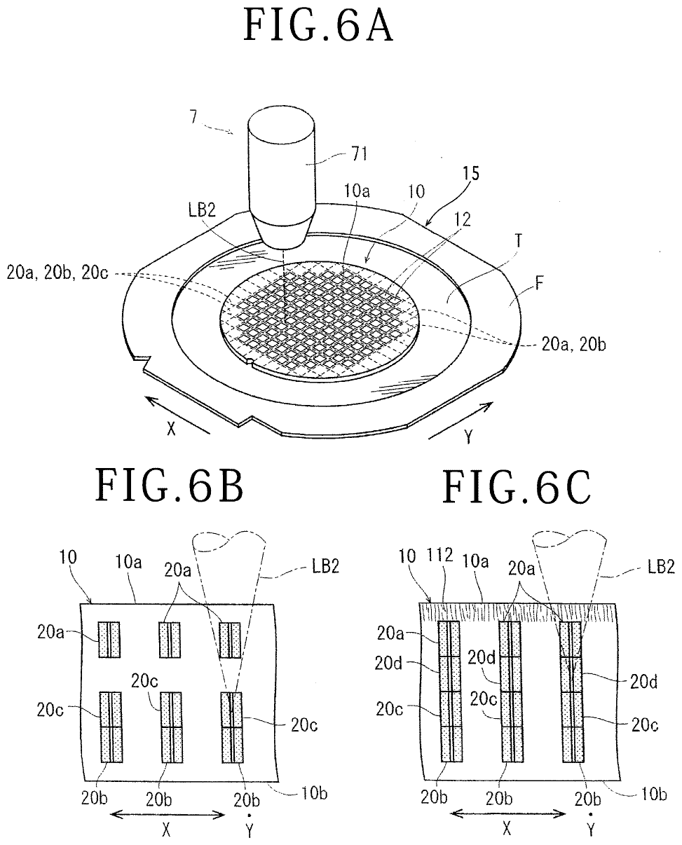

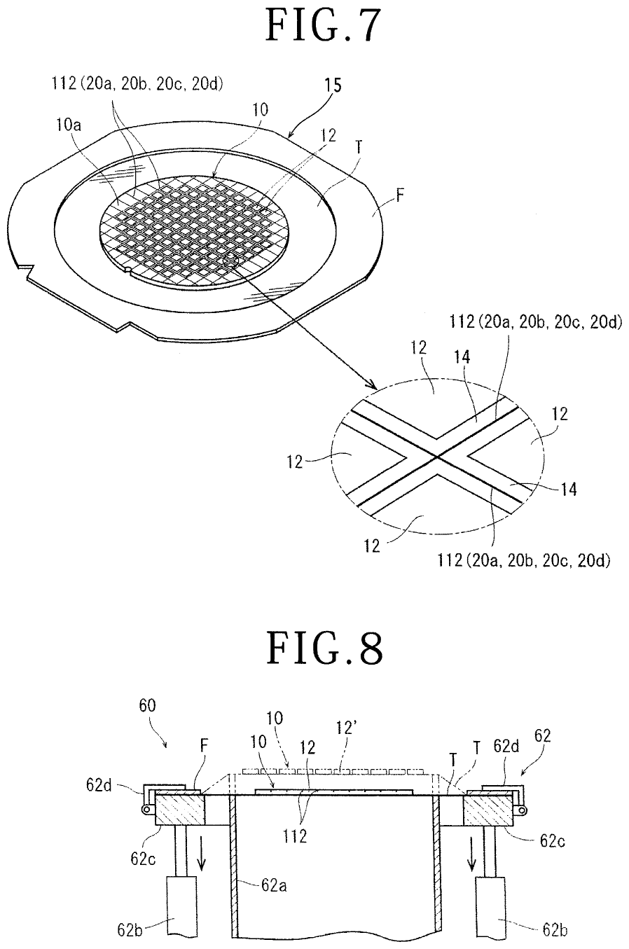

After the above-described first processing step and second processing step have been performed, a third processing step is performed. In the third processing step, the wafer 10 is irradiated on the basis of the above-described second processing conditions with the second laser beam LB2 with the focal point of the second laser beam LB2 sequentially positioned between the respective first modified layers 20 and the second modified layers 20b corresponding to the first modified layers 20a, whereby third modified layers are formed, as a third layer group, extending from the second modified layers 20b to the corresponding first modified layers 20a, and straight cracks are allowed to appear along the dicing lines 14 in the front surface 10a on which the dicing lines 14 are formed. These third modified layers formed as the third layer group by the third processing step are not limited to constitution by a single group of modified layers, and also include formation by a plurality of groups of modified layers. With reference to FIGS. 6A to 7, the third processing step will hereinafter be described more specifically.

When the third processing step is to be performed, a predetermined one of the first direction dicing lines 14 with the first modified layers 20a and second modified layers 20b formed therein is positioned right below the condenser 71 of the above-described laser beam irradiation unit 7 as depicted in FIG. 6A. Here, the laser beam irradiation unit 7 is set by the controller 50 on the basis of the above-described second processing conditions such that the second laser beam LB2, which is of the wavelength having transmissivity for the wafer 10, and is of the relatively high power compared with the first processing conditions under which the first processing step was performed, is irradiated.

Now, as depicted in FIG. 6B, in the third processing step, the wafer 10 is irradiated with the second laser beam LB2 with the focal point of the second laser beam LB2 sequentially positioned between the respective first modified layers 20a and the second modified layers 20b corresponding to the first modified layer 20a and on sides of the second modified layers 20b, and, in addition, the X-axis moving mechanism 4a is operated, whereby a first row of third modified layers 20c is formed along the predetermined one first direction dicing line 14 of the wafer 10 so that the third modified layers 20c come into contact with upper ends of the second modified layers 20b, respectively. As with the first modified layers 20a and the second modified layers 20b, third modified layers 20c in the first row are each preferably formed of a fine hole and an amorphous region surrounding the fine hole.

Next, the above-described second laser beam LB2 is irradiated, and, in addition, as with the moving mechanism 4 when the first modified layers 20a and the second modified layers 20b were formed, the X-axis moving mechanism 4a, the Y-axis moving mechanism 4b, and the rotary drive mechanism are operated, so that a plurality of rows of third modified layers 20c, the rows being of the same number as all the dicing lines 14, is formed as a third layer group at the above-described position in the thickness direction of the wafer 10 along all the dicing lines 14 of the wafer 10.

Now, as depicted in FIG. 6C, if the third modified layers 20c as the third layer group have a height dimension insufficient to reach the corresponding first modified layers 20a as the first layer group as depicted in FIG. 6B, the wafer 10 is irradiated with the second laser beam LB2 with the focal point of the second laser beam LB2 sequentially positioned between the respective first modified layers 20a and the third modified layers 20c corresponding to the first modified layers 20a, and, in addition, the X-axis moving mechanism 4a is operated, whereby a first row of additional third modified layers 20d is formed along a predetermined one of the first direction dicing lines 14, in contact with upper ends of the corresponding third modified layers 20c, and extending to the corresponding first modified layers 20a. As with the third modified layers 20c as the third layer group, the additional third modified layers 20d in the first row are each preferably formed of a fine hole and an amorphous region surrounding the fine hole. It is to be noted that, as a condenser lens to be used when the above-described third modified layers 20c and additional third modified layers 20d are formed as the third layer group and fourth layer group, respectively, one satisfying similar conditions as the number of apertures of the condenser lens used when the first modified layers 20a were formed as the first layer group is selected.

As described above, the wafer 10 is irradiated with the second layer beam LB2 with the focal point of the second laser beam LB2 sequentially positioned between the respective first modified layers 20a and the second modified layers 20b corresponding to the first modified layers 20a, whereby the above-described third modified layers 20c and additional third modified layers 20d are formed as the third layer group and fourth layer group, respectively, the third modified layers 20c and the additional third modified layers 20d reach the first modified layers 20a, and as depicted in FIG. 6C, cracks 112 are directed to and formed in the first modified layers 20a. As a consequence, the non-meandering straight cracks 112 are allowed to appear along all the dicing lines 14 as depicted in FIG. 7, and the third processing step is completed. It is to be noted that the number of layer groups of third modified layers to be formed in the third processing step is not limited to constitution by the two layer groups of modified layers (the third modified layers 20c as the third layer group and the additional third modified layers 20d as the fourth layer group) as in the above-described embodiment, and is appropriately determined according to the thickness of the wafer 10 and the respective heights of the first to forth layer groups. Described specifically, it is necessary to form only a single layer group of third modified layers if modified layers that extend from the second modified layers 20b to the first modified layers 20a are formed by forming the third modified layers 20c as the third layer group. Further, three or more layer groups of third modified layers may also be formed.

### (Dividing Step)

After the cracks 112 have been formed as division starting points by the above-described first to third processing steps, a dividing step is performed. In the dividing step, an external force is applied to the wafer 10 to divide the wafer 10 into individual device chips. No particular limitation is imposed on how the external force is applied to the wafer 10, and the dividing step can be performed, for example, using a dividing machine 60 depicted in FIG. 8.

The dividing machine 60, an outline of which is depicted in FIG. 8, includes expanding means 62. The expanding means 62 includes a cylindrical expansion drum 62a, a plurality of air cylinders 62b disposed adjacent the expansion drum 62a at intervals in a peripheral direction and extending upward, an annular holding member 62c connected to upper ends of the respective air cylinders 62b, and a plurality of clamps 62d arranged at intervals in the peripheral direction on an outer peripheral edge portion of the holding member 62c. The expansion drum 62a has an inner diameter greater than the diameter of the wafer 10, and an outer diameter smaller than an inner diameter of the annular frame F. Meanwhile, the holding member 62c has a diameter dimension corresponding to that of the annular frame F, so that the annular frame F is configured to be placed on a flat upper surface of the holding member 62c.

As illustrated in FIG. 8, the air cylinders 62b are configured to lift up and down the holding member 62c between a home position, at which the upper surface of the holding member 62c is at substantially the same height as an upper end of the expansion drum 62a, and an expanding position, at which the upper surface of the holding member 62c is located lower than the upper end of the expansion drum 62a. It is to be noted that, in FIG. 8, the wafer 10 held on the depicted self-adhesive tape T is presented to be lifted up and down along with the expansion drum 62a (as indicated by solid lines and two-dot chain lines) for the convenience of description, although the holding member 62c is lifted up and down actually.

When an external force is to be applied to the wafer 10 by expanding the self-adhesive tape T with the wafer 10 supported thereon, the annular frame F is first placed on the upper surface of the holding member 62c positioned at the home position with the front surface 10a of the wafer 10, on which the first processing step and the second processing step have been performed and the devices 12 are formed, directed upward, and the annular frame F is fixed by the clamps 62d. The holding member 62c is then lifted down to the expanding position, whereby as indicated by the two-dot chain lines in FIG. 8, the wafer 10 is expanded along with the self-adhesive tape T, an external force is radially applied to the wafer 10, and the wafer 10 bonded to the self-adhesive tape T is divided into individual device chips 12′. As a consequence, the divided device chips 12′ divided from the wafer 10 can be picked up by appropriate pickup means (depiction omitted) from the wafer, so that the picked-up device chips 12′ can be transferred to the next step, or can be placed in an appropriate storage case.

As described above, the relatively large, non-meandering straight cracks 112 have been formed along the dicing lines 14 of the wafer 10 before the dividing step is performed. It is therefore possible to reduce dividing load when the above-described dividing step is performed and to appropriately divide the wafer 10 into individual the device chips 12′ with high precision without causing chipping.

The method that divides the wafer 10 into the individual device chips 12′ by applying an external force to the wafer 10 is not limited to the above-described method that uses the dividing machine 60. For example, the wafer 10 can also be divided into the individual device chips 12′ by placing the wafer 10 on a pad having elasticity and applying an external force to the wafer 10 while a hard roller is pressed against the wafer 10 along the dicing lines 14 from above or a wedge-shaped pressing member is pressed against the wafer 10, which is placed on the pad, along the dicing lines 14 to apply an external force to the wafer 10.

In the above-described embodiment, the description is made about the example in which the wafer 10 is formed with the SiC substrate. However, the present invention is not limited to the example. In a case of a GaN substrate, a diamond substrate, or a sapphire substrate, for example, similar advantageous effects can be exhibited by applying the above-described embodiment. When the above-described embodiment is applied, laser processing conditions to be followed when the first processing step and the second processing step are performed are appropriately adjusted according to the material, thickness, and the like of a wafer to be processed.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A processing method of a wafer, on which a plurality of devices is formed on a front surface thereof and is defined by a plurality of intersecting dicing lines, by dividing the wafer into individual device chips, the processing method comprising:
a first processing step of irradiating the wafer with a first laser beam of a wavelength having transmissivity for the wafer and of a first power with a focal point of the first laser beam sequentially positioned on the respective dicing lines near the front surface whereby first modified layers are formed with no cracks reaching the front surface along the respective dicing lines;
a second processing step of irradiating the wafer with a second laser beam of a wavelength having transmissivity for the wafer and of a second power higher than the first power with a focal point of the second laser beam sequentially positioned corresponding to the respective dicing lines on an inner side of a back surface of the wafer whereby second modified layers are formed along the respective dicing lines;
a third processing step of irradiating the wafer with the second laser beam with the focal point of the second laser beam sequentially positioned between the first modified layers and the second modified layers which correspond to the first modified layers, respectively, whereby third modified layers are formed extending from the second modified layers to the first modified layers, respectively, and, at the same time, straight cracks are allowed to appear on the front surface of the wafer, where the dicing lines are formed, along the dicing lines; and
a dividing step of applying an external force to the wafer whereby the wafer is divided into the individual device chips.

2. The processing method according to claim 1, wherein the first modified layers, the second modified layers, and the third modified layers are each constituted of a shield tunnel that is formed of a fine hole and an amorphous region surrounding the fine hole.

3. The processing method according to claim 1, wherein the wafer is irradiated from the front surface with the first laser beam in the first processing step, and with the second laser beam in the second and third processing steps.

4. The processing method according to claim 1, wherein the wafer is selected from a group consisting of a silicon carbide wafer, a gallium nitride wafer, a diamond wafer, and a sapphire wafer.
